(19) United States
(12) Patent Application Publication
(10) Pub. No.: US 2016/0144396 A1
(43) Pub. Date: May 26, 2016

(54) THIN FILM DEPOSITION MASK ASSEMBLY AND IN-LINE TYPE THIN FILM DEPOSITION APPARATUS INCLUDING THE SAME

(71) Applicant: SAMSUNG DISPLAY CO., LTD., Yongin-City (KR)

(72) Inventors: Hee Sun JANG, Incheon (KR); Joo Seob AHN, Seoul (KR); Jae Ha LIM, Hwaseong-si (KR); Yong Hyun JIN, Seoul (KR)

(21) Appl. No.: 14/743,757

(22) Filed: Jun. 18, 2015

(30) Foreign Application Priority Data
Nov. 24, 2014 (KR) 10-2014-0164743

(51) Int. Cl. B05C 21/00

(52) U.S. Cl. CPC B05C 21/005

(57) ABSTRACT

A thin film deposition mask assembly and an in-line type thin film deposition apparatus for deposition of an organic material on a substrate, the mask assembly including a carrier, the carrier being configured to mount and carry a substrate; and a mask, the mask being integrally coupled with the carrier, and having an opening for depositing an organic material on the substrate.

### CROSS-REFERENCE TO RELATED APPLICATION

Korean Patent Application No. 10-2014-0164743, filed on Nov. 24, 2014, in the Korean Intellectual Property Office, and entitled: “Thin Film Deposition Mask Assembly and In-Line Type Thin Film Deposition Apparatus Comprising the Same,” is incorporated by reference herein in its entirety.

### BACKGROUND

1. Field

Embodiments relate to a thin film deposition mask assembly and an in-line type thin film deposition apparatus including the same.

2. Description of the Related Art

In an organic material deposition process of a large-sized organic light emitting device, a mask for film-forming a display area may be used.

The above information disclosed in this Background section is only for enhancement of understanding of the background of the described technology and therefore it may contain information that does not form the prior art that is already known in this country to a person of ordinary skill in the art.

### SUMMARY

Embodiments are directed to a thin film deposition mask assembly and an in-line type thin film deposition apparatus including the same.

The embodiments may be realized by providing a thin film deposition mask assembly including a carrier, the carrier being configured to mount and carry a substrate; and a mask, the mask being integrally coupled with the carrier, and having an opening for depositing an organic material on the substrate.

The mask may include an open mask that masks a non-display area of the substrate for deposition of the organic material on a display area of the substrate, or a pattern mask that has an opening pattern for deposition of each pixel on the display area of the substrate.

The open mask or the pattern mask may be integrally coupled with the carrier.

The open mask and the pattern mask may be coupleable by male and female coupling.

The open mask and the pattern mask may be coupleable by magnetic force.

The open mask may include alloy steel.

The open mask may include a polyethylene terephthalate film.

The embodiments may be realized by providing an in-line type thin film deposition apparatus for deposition of an organic material on a substrate, the apparatus including a plurality of processing chambers, the plurality of processing chambers being maintainable in a vacuum; a plurality of deposition sources that supply an organic material; and a mask that is integrally coupled with a carrier, the mask having an opening for deposition of the organic material on the substrate.

The processing chamber may include an alignment chamber in which the substrate is aligned with and attached onto the carrier; an organic deposition chamber in which an organic material is deposited on the substrate; and a mask supply chamber in which another mask is provided onto the carrier as the carrier moves in in the organic deposition chamber.

The mask may include an open mask that masks a non-display area of the substrate for deposition of the organic material on a display area of the substrate, or a pattern mask that has an opening pattern for deposition of each pixel on the display area of the substrate.

One of the pattern mask or the open mask may be integrally coupled with the carrier, and the mask supply chamber may provide the other of the pattern mask or the open mask to be coupled with the open mask or the pattern mask that is integrally coupled with the carrier.

### BRIEF DESCRIPTION OF THE DRAWINGS

Features will be apparent to those of skill in the art by describing in detail exemplary embodiments with reference to the attached drawings in which:

FIG. 1 illustrates a diagram of a state in which an open mask is coupled to a carrier in a thin film deposition mask assembly according to an exemplary embodiment.

FIG. 2 illustrates a diagram of a state in which a pattern mask is coupled to the open mask by male and female coupling in the thin film deposition mask assembly according to the exemplary embodiment.

FIG. 3 illustrates a diagram of a state in which the pattern mask is coupled to the open mask by magnetic force in the thin film deposition mask assembly according to the exemplary embodiment.

FIG. 4 illustrates a diagram of a state in which an open mask is coupled to a pattern mask by male and female coupling in the thin film deposition mask assembly according to another exemplary embodiment.

FIG. 5 illustrates a diagram schematically showing an in-line type thin film deposition apparatus according to an exemplary embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. Like reference numerals refer to like elements throughout.

It will be understood that when an element such as a layer, film, region, or substrate is referred to as being “on” another element, it can be directly on the other element or intervening elements may also be present.

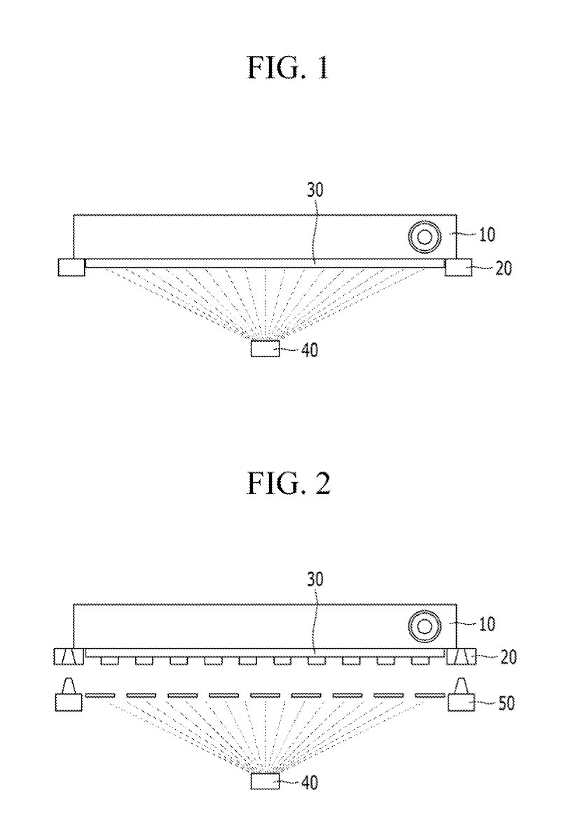

Hereinafter, a thin film deposition mask assembly according to an exemplary embodiment will be described in detail with reference to FIGS. 1 and 2.

FIG. 1 illustrates a diagram of a state in which an open mask is coupled to a carrier in a thin film deposition mask assembly according to an exemplary embodiment, and FIG. 2 illustrates a diagram of a state in which a pattern mask is coupled to the open mask by male and female coupling in the thin film deposition mask assembly according to the exemplary embodiment.

During a process, an open mask 20 may be input to or coupled with a carrier 10 (on which a, e.g., glass, substrate 30 is mounted) to deposit an, e.g., organic, material on the substrate 30. Then, the open mask 20 may be removed, and an, e.g., organic, material for forming each pixel of red R, green G, and blue B may be deposited on the display area of the entire surface of the substrate 30 while a pattern mask 50 and the carrier 10 are spaced apart from each other by a distance ‘d’. In an implementation, the distance ‘d’ may be about 250 μm. In an implementation, when the open mask 20 is input, an organic material may be film-formed on the entire surface of the glass substrate 30 while being spaced apart from each other by the distance ‘d’.

Using such a structure or apparatus may include separate steps of coupling and removing the open mask 20, and may include using a separate mask supply device. As a result, there may be a spatial limitation, and a shadow phenomenon may occur due to a gap between the substrate and the masks 20 and 50.

Accordingly, without requiring a separate open mask supply device and in order to help minimize the gap between the substrate 30 and the masks 20 and 50, in the thin film deposition mask assembly according to the exemplary embodiment, as illustrated in FIG. 1, the open mask 20 may be integrally manufactured with the carrier 10, and the open mask 20 and the pattern mask 50 may be coupled with each other. For example, the open mask 20 may be monolithically formed in a one-piece structure with the carrier 10 or the open mask 20 may be fixedly attached to the carrier 10.

Referring to FIG. 1, the thin film deposition mask assembly may include the carrier 10 (for mounting and carrying the substrate 30), and the open mask 20 (which is integrally coupled with the carrier 10 and that masks, overlies, or covers a non-display area. Thus, the organic material may be deposited on an entire surface of the display area of the substrate 30. The open mask 20 may have a masking region corresponding to, covering, or overlying the (to be formed) non-display area of the substrate 30. For example, the masking region may contact and may be integrally coupled with the carrier 10. The open mask 20 may include a region (other than or complementary to the masking region) that has an opening, e.g., that is an open space, so that an organic material may be deposited on the (to be formed) display area of the substrate 30.

In such a structure, the open mask 20 and the carrier 10 may be integrally configured, a mask supply device for inputting, providing, or coupling the open mask 20 with the carrier 10 may be omitted, and a shadow phenomenon due to a gap between the open mask 20 and the glass substrate 30 may be reduced and/or prevented.

In an implementation, the open mask 20 may include, e.g., alloy steel (such as Invar®). The alloy steel is basically steel with an improved property so as to be suitable for a particular purpose by adding one or many alloy elements into carbon steel. In an implementation, the alloy element may include, e.g., nickel (Ni), chromium (Cr), manganese (Mn), molybdenum (Mo), vanadium (V), titanium (Ti), cobalt (Co), or the like.

In an implementation, the open mask 20 may include, e.g., a polyethylene terephthalate (PET) film.

Referring to FIG. 2, in the in-line type thin film deposition apparatus, during a deposition period using the pattern mask 50, the pattern mask 50 may be input or provided to be coupled with the carrier-integrated open mask 20 while being carried. The open mask 20 and the pattern mask 50 (as an adapter form) may be assembled or coupled, e.g., may be coupleable, by male and female coupling. For example, a groove may be provided at a masked portion of the open mask 20, and a protruding edge or protrusion of the pattern mask 50 may be inserted into and coupled with the groove. In an implementation, as an opposite structure, a groove may be provided in the pattern mask 50, and a protrusion may be provided on the open mask 20, and the groove and the protrusion may be coupled with each other.

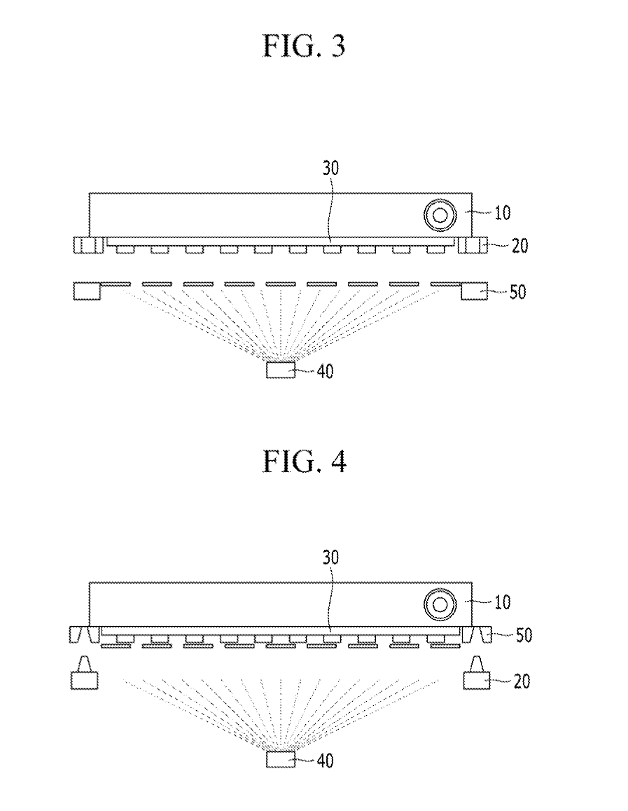

FIG. 3 illustrates a diagram of a state in which the pattern mask is coupled to the open mask by magnetic force in the thin film deposition mask assembly according to the exemplary embodiment.

Referring to FIG. 3, the open mask 20 and the pattern mask 50 may be coupled or may be coupleable with each other by magnetic force. In an implementation, the open mask 20 and the pattern mask 50 may be assembled by magnetic coupling of permanent magnets having different polarities. In an implementation, the open mask 20 and the pattern mask 50 may be coupled by magnetic force in addition to male and female coupling illustrated in FIG. 2.

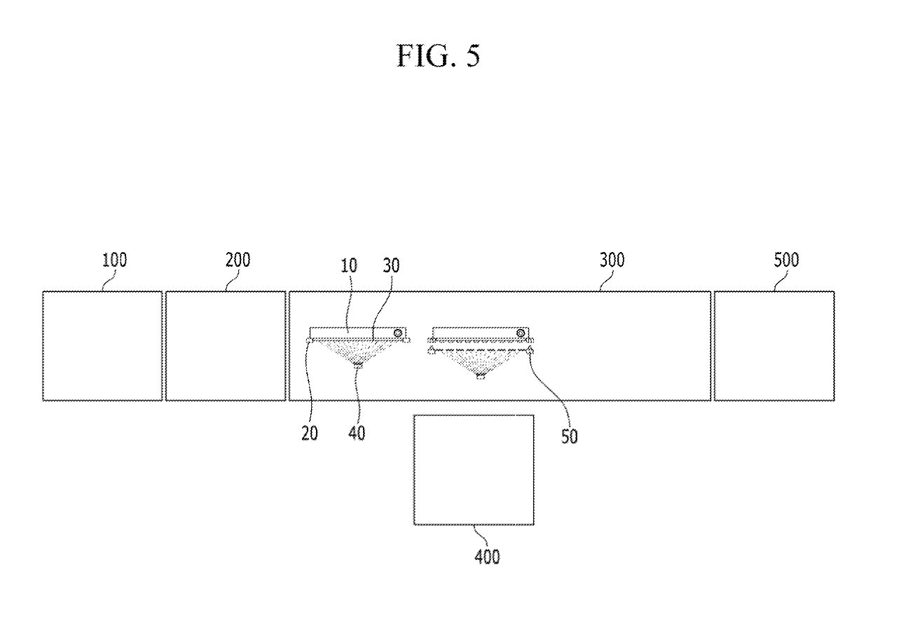

FIG. 4 illustrates a diagram of a state in which an open mask is coupled to a pattern mask by male and female coupling in the thin film deposition mask assembly according to another exemplary embodiment.

In the exemplary embodiment illustrated in FIG. 4, the carrier 10 and the pattern mask 50 may be integrally configured, and during the deposition process, the open mask 20 may be coupled to the pattern mask 50. For example, the pattern mask 50 may be monolithically formed in a one-piece structure with the carrier 10 or the pattern mask 50 may be fixedly attached to the carrier 10.

The thin film deposition mask assembly according to the exemplary embodiment may include a carrier 10 (for mounting and carrying a substrate), a pattern mask 50 (that is integrally coupled with the carrier 10) including an opening pattern for depositing each pixel on a display area of the substrate 30, and an open mask 20 (coupled with the pattern mask 50) that is masked in or that covers a non-display area so that an organic material may be deposited on the entire surface of the display area of the substrate 30.

In an implementation, the open mask 20 may include, e.g., an alloy steel or a polyethylene terephthalate (PET) film.

As illustrated in FIG. 4, the pattern mask 50 may be integrally configured with the carrier 10, and the masking portion of the open mask 20 may be assembled or attached at the edge of the pattern mask 50 by male and female coupling. In an implementation, the pattern mask 50 and the open mask 20 may be coupled with each other by magnetic force, and/or coupled with each other by magnetic force in addition to male and female coupling.

FIG. 5 illustrates a diagram schematically showing an in-line type thin film deposition apparatus according to an exemplary embodiment.

Referring to FIG. 5, in an in-line type thin film deposition apparatus, in a mask supply chamber 500, an open mask supply chamber may be omitted, and only a pattern mask supply chamber may be present. In an implementation, the open mask 20 may be integrally configured with the carrier, and other parts of the in-line type thin film deposition apparatus according to the exemplary embodiment may be the same as or similar to another suitable in-line type thin film deposition apparatus.

For example, the in-line type thin film deposition apparatus according to an embodiment may include a plurality of processing chambers 100, 200, 300, 400, and 500 (which may be maintained in a vacuum), a plurality of deposition sources 40 (that supply, e.g., an organic material), and masks 20 and 50 (coupled with, e.g., integrally coupled with the carrier 10 and/or with each other). As described above, the masks 20 and 50 may have openings so as to deposit the organic material on the substrate 30, and may be masked.

For example, the processing chambers 100, 200, 300, 400, and 500 may include an alignment chamber 100 (in which the substrate 30 may be attached to the carrier 10 after aligning a position to some degree), a loading chamber 200 (for providing the substrate 30 that has been mounted on the carrier 10 into an organic deposition chamber 300), the organic deposition chamber 300 (in which an organic material may be deposited on the substrate 30, e.g., for forming a pixel on a display area of the substrate 30), a mask supply chamber 400 (in which masks 20 and 50 may be supplied to the carrier 10 that is moving in the organic deposition chamber 300), and an unloading chamber 500 (in which the substrate 30, on which the organic material has been deposited, may be unloaded).

Here, the masks 20 and 50 may include the open mask 20 (that covers the non-display area so that the organic material is only deposited on the entire surface of the display area of the substrate 30) and a pattern mask 50 (that has an opening pattern so that each pixel is deposited on the display area of the substrate 30).

In FIG. 5, an example in which the pattern mask 50 is coupled to the open mask 20 (which open mask 20 is integrally coupled with the carrier 10) is illustrated, and the mask supply chamber 400 may be a pattern mask supply chamber. In an implementation, the open mask 20 may be coupled to the pattern mask 50 (which pattern mask 50 is integrally coupled with the carrier 10) and, in this case, the mask supply chamber 400 may be an open mask supply chamber.

The plurality of deposition sources 40 for depositing the organic material on the substrate 30 along a path on which the substrate 30 moves may be provided in the organic deposition chamber 300. The plurality of deposition sources 40 (supplying the organic material to the entire surface of the substrate 30 by the open mask 20), and the deposition sources 40 (corresponding to each pattern mask 50 corresponding to each pixel of red R, green G, and blue B of the display area of the substrate) may be disposed in a progressing direction of the substrate 30, e.g., may be sequentially disposed in the organic deposition chamber 300.

As the carrier 10 is carried, the pattern mask 50 may be coupled with the open mask 20, and the pattern mask 50 may have an opening pattern so as to deposit each pixel on the display area of the substrate 30. Before the substrate is transferred to the unloading chamber 500, the carrier 10 may be detached from the substrate 30 to be transferred to the loading chamber 200 again, and a new substrate 30 may be mounted on the carrier 10.

When the in-line type thin film deposition apparatus according to an embodiment uses an open mask-integrated carrier or a pattern mask-integrated carrier, a separate open mask supply device or pattern mask supply device (and a space for the separate open mask supply device or pattern mask supply device) may be omitted, thereby helping to reduce manufacturing costs.

In the thin film deposition mask assembly and the in-line type thin film deposition apparatus including the same according to an embodiment, in a large OLED TV manufacturing process, many masks may not need to be separately provided, and a large-area space may not be needed. Thus, investment costs of equipment may be reduced and a shadow phenomenon due to a gap between a substrate, an open mask, and a pattern mask may be reduced and/or prevented.

By way of summation and review, a mask may include an open mask for film-forming an entire surface of a glass substrate, and a pattern mask for film-forming each pixel of red R, green G, and blue B of the display area. For example, in an in-line type thin film deposition apparatus, the glass substrate may be input to an alignment chamber to be aligned with and attached to a carrier. In addition, the glass substrate mounted on the carrier may be input to an organic deposition chamber through a loading chamber to move in one direction, and an open mask may be provided from an open mask supply chamber to be coupled onto the glass substrate. In the organic deposition chamber, after an organic material is deposited on an entire surface of the glass substrate through the open mask, the open mask may be removed and a pattern mask may be provided from the pattern mask supply chamber to be coupled onto the glass substrate. Each pixel of red R, green G, and blue B in the display area of the glass substrate may be film-formed using the pattern mask. Thereafter, if desired, the open mask may be provided again to form an organic film on the entire surface of the glass substrate. Thereafter, in an unloading chamber, the film-formed glass substrate may be detached from the carrier.

As such, in the in-line type thin film deposition apparatus, processes of inputting and removing the mask may be performed many times, manufacturing of many masks may be performed, and a large-area space for cleaning and storing may be used. Further, the mask may be periodically replaced and manufacturing cost may be increased, and it may be difficult to hold and store the mask.

The embodiments may provide a thin film deposition mask assembly having advantages of reducing investment costs of equipment and removing or reducing a shadow phenomenon due to a gap among a substrate, an open mask, and a pattern mask, because additional equipment such as a mask supplying apparatus are not required, by introducing to an in-line type thin film deposition apparatus the thin film deposition mask assembly in which a mask and a carrier are integrally configured.

The embodiments may provide an in-line type thin film deposition apparatus including a thin film deposition mask assembly in which a mask and a carrier are integrally configured.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

<Description of symbols>

| | |
|---|---|
| 10: Carrier | 20: Open mask |
| 30: Substrate | 40: Deposition source |
| 50: Pattern mask | 100: Alignment chamber |
| 200: Loading chamber | 300: Organic deposition chamber |
| 400: Mask supply chamber | 500: Unloading chamber |

What is claimed is:

1. A thin film deposition mask assembly, comprising:
a carrier, the carrier being configured to mount and carry a substrate; and
a mask, the mask:
being integrally coupled with the carrier, and
having an opening for depositing an organic material on the substrate.

2. The thin film deposition mask assembly as claimed in claim 1, wherein the mask includes:
an open mask that masks a non-display area of the substrate for deposition of the organic material on a display area of the substrate, or
a pattern mask that has an opening pattern for deposition of each pixel on the display area of the substrate.

3. The thin film deposition mask assembly as claimed in claim 2, wherein the open mask or the pattern mask is integrally coupled with the carrier.

4. The thin film deposition mask assembly as claimed in claim 2, wherein the open mask and the pattern mask are coupleable by male and female coupling.

5. The thin film deposition mask assembly as claimed in claim 2, wherein the open mask and the pattern mask are coupleable by magnetic force.

6. The thin film deposition mask assembly as claimed in claim 2, wherein the open mask includes alloy steel.

7. The thin film deposition mask assembly as claimed in claim 2, wherein the open mask includes a polyethylene terephthalate film.

8. An in-line type thin film deposition apparatus for deposition of an organic material on a substrate, the apparatus comprising:
a plurality of processing chambers, the plurality of processing chambers being maintainable in a vacuum;
a plurality of deposition sources that supply an organic material; and
a mask that is integrally coupled with a carrier, the mask having an opening for deposition of the organic material on the substrate.

9. The in-line type thin film deposition apparatus as claimed in claim 8, wherein the processing chamber includes:
an alignment chamber in which the substrate is aligned with and attached onto the carrier;
an organic deposition chamber in which an organic material is deposited on the substrate; and
a mask supply chamber in which another mask is provided onto the carrier as the carrier moves in the organic deposition chamber.

10. The in-line type thin film deposition apparatus as claimed in claim 8, wherein the mask includes:
an open mask that masks a non-display area of the substrate for deposition of the organic material on a display area of the substrate, or
a pattern mask that has an opening pattern for deposition of each pixel on the display area of the substrate.

11. The in-line type thin film deposition apparatus as claimed in claim 10, wherein:
one of the pattern mask or the open mask is integrally coupled with the carrier, and
the mask supply chamber provides the other of the pattern mask or the open mask to be coupled with the open mask or the pattern mask that is integrally coupled with the carrier.
